(19) United States
(12) Patent Application Publication
(10) Pub. No.: US 2022/0302679 A1
(43) Pub. Date: Sep. 22, 2022

(54) VERTICAL CAVITY SURFACE EMITTING LASER DEVICE

(71) Applicant: ams Sensors Asia Pte. Ltd., Singapore (SG)

(72) Inventors: Guoyang Xu, Mercerville, NJ (US); Qing Wang, Plainsboro, NJ (US); Feng Zhao, Lancaster, NY (US)

(21) Appl. No.: 17/603,909

(22) PCT Filed: Apr. 16, 2020
(86) PCT No.: PCT/SG2020/050238

§ 371 Date: Oct. 14, 2021

Related U.S. Application Data
(60) Provisional application No. 62/835,106, filed on Apr. 17, 2019.

(51) Int. Cl. H01S 5/183; H01S 5/026

(52) U.S. Cl. CPC H01S 5/18302; H01S 5/18305; H01S 5/18361; H01S 5/026

(57) ABSTRACT

A vertical cavity surface emitting laser (VCSEL) device comprises an interior light generating region, an exterior light emitting surface, and a spatial modulation region monolithically integrated with the interior light generating region so that the spatial modulation region is located between the interior light generating region and the exterior light emitting surface. The spatial modulation region is configured to shape the light generated by the interior light generating region before the generated light is emitted from the exterior light emitting surface. The VCSEL device may be configured to emit a beam of light along a predetermined direction, to emit a beam of light having a predetermined beam divergence, and/or to emit a beam of light having a predetermined shape or structure transverse to a direction of propagation so that the beam of light forms a predetermined spot or pattern of light when projected onto a surface. A plurality of VCSEL devices and a method for use in manufacturing a VCSEL device are also disclosed.

### FIELD

The present disclosure relates to a vertical cavity surface emitting laser (VCSEL) device for emitting a shaped beam of light and, in particular though not exclusively, for emitting a beam of light along a predetermined direction, for emitting a beam of light having a predetermined beam divergence, and/or for emitting a beam of light having a predetermined shape or structure transverse to a direction of propagation so that the beam of light forms a predetermined spot or pattern of light when projected onto a surface.

### BACKGROUND

It is known to use VCSELs to emit light for various technical applications. A conventional VCSEL is generally configured to emit a circular or elliptical beam in a direction normal to a light emitting surface of the VCSEL. Where a particular technical application requires a shaped beam, such as a beam having a specific direction of emission, a specific beam divergence, or a specific shape or structure transverse to a direction of propagation, it is also known to use a VCSEL system or arrangement including a VCSEL and one or more additional beam-shaping components in optical alignment with the VCSEL to shape the circular beam of light after emission from the VCSEL. Such VCSEL systems or arrangements may, for example, include a VCSEL in optical alignment with one or more lenses, one or more micro-optics, one or more optical masks or the like.

### SUMMARY

According to an aspect of the present disclosure there is provided a vertical cavity surface emitting laser (VCSEL) device comprising:

an interior light generating region;

an exterior light emitting surface; and

a spatial modulation region monolithically integrated with the interior light generating region so that the spatial modulation region is located between the interior light generating region and the exterior light emitting surface,

wherein the spatial modulation region is configured to shape the light generated by the interior light generating region before the generated light is emitted from the exterior light emitting surface.

Such a VCSEL device may be configured to emit a shaped beam of light. For example, such a VCSEL device may be configured to emit a beam of light along a predetermined direction, to emit a beam of light having a predetermined beam divergence, and/or to emit a beam of light having a predetermined shape or structure for forming a predetermined spot or pattern of light when projected onto a surface. Such a VCSEL device may be simpler, more compact, and/or more robust than a known VCSEL system or arrangement for emitting a shaped beam of light, which known VCSEL system or arrangement comprises a conventional VCSEL and one or more additional optical beam-shaping components in optical alignment with the conventional VCSEL. Such a VCSEL device also avoids any requirement for alignment between the VCSEL device and one or more additional optical beam-shaping components in order to form a shaped beam of light.

The interior light generating region, the spatial modulation region, and the exterior light emitting surface may be arranged along a VCSEL axis. The spatial modulation region may be configured to impose a transverse spatial modulation relative to the VCSEL axis on the light generated by the interior light generating region before the generated light is emitted from the exterior light emitting surface. The spatial modulation region may be configured to impose a transverse spatial modulation in at least one of amplitude, phase and polarization on the light generated by the interior light generating region before the generated light is emitted from the exterior light emitting surface. The spatial modulation region may serve as, or may constitute, an integrated beam shaper, for example a diffractive or a holographic integrated beam shaper.

The spatial modulation region may define an outer surface which is directed away from the interior light generating region, wherein the outer surface of the spatial modulation region has an uneven profile.

The spatial modulation region may define a plurality of diffractive element regions, each diffractive element region defining a corresponding outer surface directed away from the interior light generating region, and each diffractive element region having a corresponding thickness measured in a direction parallel to the VCSEL axis so that the outer surface of each diffractive element region is located a corresponding distance from the interior light generating region measured in a direction parallel to the VCSEL axis, and wherein the outer surfaces of the plurality of diffractive element regions together define the outer surface of the spatial modulation region.

The thicknesses of at least two of the diffractive element regions may be different.

The thickness of each diffractive element region may be selected from a finite group of two or more different thicknesses.

In effect, the outer surface of the spatial modulation region may be considered to comprise or define a diffractive optical region or a blazed diffraction grating.

The outer surface of the spatial modulation region may be defined by one or more steps, each step comprising removing, for example etching, material from one or more of the outer surfaces of one or more of the diffractive element regions.

The plurality of diffractive element regions may be defined lithographically using one or more lithography masks.

The thickness of each diffractive element region may be selected from a group of 2^{N} different thicknesses, where N is the number of lithography masks used to define the outer surface of the spatial modulation region.

The outer surface of the spatial modulation region may be defined by an imprinting, molding or stamping process. For example, the outer surface of the spatial modulation region may be defined using a mold or a stamp such as a master mold or a master stamp.

The outer surface of the spatial modulation region may be defined using a selective growth process such as atomic layer deposition.

Each diffractive element region of the spatial modulation region may adjoin, or be contiguous with, at least one adjacent diffractive element region of the spatial modulation region.

Each diffractive element region may be configured so that the outer surfaces of the plurality of diffractive element regions achieve a 100% fill factor of the outer surface of the spatial modulation region. For example, each diffractive element region may have an outer surface of any shape and/or size so that the outer surfaces of the plurality of diffractive element regions achieve a 100% fill factor of the outer surface of the spatial modulation region. Two or more of the diffractive element regions may have outer surfaces having the same shape and/or size. Two or more of the diffractive element regions may have outer surfaces having different shapes and/or sizes.

At least two of the outer surfaces of the diffractive element regions may be triangular, quadrilateral, square, rectangular, or hexagonal in shape.

The outer surfaces of all of the diffractive element regions may have the same shape and size.

At least two of the outer surfaces of the diffractive element regions may have different shapes and/or sizes.

The outer surfaces of the diffractive element regions may have a minimum feature size of 0.5 μm or less, 0.2 μm or less, or 0.1 μm or less.

The exterior light emitting surface may be defined by the outer surface of the spatial modulation region.

The VCSEL device may comprise a protective region, wherein the protective region covers the spatial modulation region, an outer surface of the protective region defines the exterior light emitting surface, and wherein the protective region is configured for transmission of light generated by the interior light generating region.

The protective region may comprise at least one of: silicon dioxide, silica, silicon nitride, and a polymer.

The interior light generating region may comprise one or more layers of semiconductor material.

The interior light generating region may comprise one or more quantum wells and a plurality of barriers, wherein each quantum well is located between two of the barriers.

The interior light generating region may comprise at least one of gallium arsenide (GaAs), aluminium gallium arsenide (AlGaAs) and indium gallium arsenide (InGaAs).

The interior light generating region may comprise one or more gallium arsenide (GaAs) quantum wells and a plurality of aluminium gallium arsenide (AlGaAs) barriers, wherein each gallium arsenide (GaAs) quantum well is located between two of the aluminium gallium arsenide (AlGaAs) barriers.

The interior light generating region may comprise one or more indium gallium arsenide (InGaAs) quantum wells and a plurality of gallium arsenide (GaAs) barriers, wherein each indium gallium arsenide (InGaAs) quantum well is located between two of the gallium arsenide (GaAs) barriers.

The VCSEL device may comprise:

a substrate;

a lower mirror structure; and

an upper mirror structure,

wherein the substrate, the lower mirror structure, the interior light generating region, the upper mirror structure, and the spatial modulation region are all monolithically integrated, and
wherein the lower mirror structure is closer to the substrate than the upper mirror structure, and the interior light generating region is located between the lower and upper mirror structures.

At least one of the lower and upper mirror structures may comprise a distributed Bragg grating structure.

The lower mirror structure, the interior light generating region, and the upper mirror structure may be grown epitaxially on the substrate.

The substrate may comprise gallium arsenide (GaAs).

At least one of the lower mirror structure and the upper mirror structure may comprise aluminium gallium arsenide (AlGaAs) and, optionally, gallium arsenide (GaAs).

The VCSEL device may be a top-emitting VCSEL device. The VCSEL device may be configured to emit light in a direction away from the substrate. The interior light generating region may be located between the substrate and the exterior light emitting surface. The upper mirror structure may be located between the interior light generating region and the spatial modulation region. The spatial modulation region may be adjacent to, and/or disposed on, the upper mirror structure. The spatial modulation region may comprise a semiconductor material which is the same as a semiconductor material of which at least one of the substrate, the lower mirror structure, the interior light generating region and the upper mirror structure comprises. The spatial modulation region may comprise GaAs and/or AlGaAs. The material of the spatial modulation region may be grown epitaxially on the upper mirror structure. The material of the spatial modulation region may be deposited on the upper mirror structure. The spatial modulation region may comprise a polymer material and/or a dielectric material.

The VCSEL device may be a bottom-emitting VCSEL device. The VCSEL device may be configured to emit light through the substrate. The substrate may be located between the interior light generating region and the exterior light emitting surface. The spatial modulation region may be located between the lower mirror structure and the exterior light emitting surface. The lower mirror structure, the interior light generating region, and the upper mirror structure may be located to, at, or on, a first side of the substrate. For example, the lower mirror structure, the interior light generating region, and the upper mirror structure may be grown epitaxially on the first side of the substrate. The spatial modulation region may be located to, at, or on, a second side of the substrate opposite to the first side of the substrate. The spatial modulation region may be defined by the substrate at the second side of the substrate. The spatial modulation region may comprise, or be formed from, material grown epitaxially or deposited on the second side of the substrate. The spatial modulation region may comprise the same material of which the substrate comprises. The spatial modulation region may comprises a polymer material and/or a dielectric material.

The interior light generating region, the spatial modulation region, and the exterior light emitting surface may be arranged along a VCSEL axis, wherein the spatial modulation region may be configured so that the VCSEL device emits a beam of light along a predetermined direction or light emitting axis, and wherein the predetermined direction or light emitting axis defines a non-zero angle relative to the VCSEL axis.

The spatial modulation region may be configured so that the VCSEL device emits a beam of light having a predetermined beam divergence.

The spatial modulation region may be configured so that the VCSEL device emits a beam of light having a predetermined shape or structure transverse to a direction of propagation so that the beam of light forms a predetermined spot or pattern of light when projected onto a surface.

The predetermined spot or pattern of light may comprise one or more predetermined shapes.

The predetermined spot or pattern of light may comprise one or more triangles, quadrilaterals, and/or polygons.

The predetermined spot or pattern of light may comprise one or more spots or dots.

The predetermined spot or pattern of light may comprise one or more circular or elliptical shapes.

The predetermined spot or pattern of light may comprise one or more rings.

The predetermined spot or pattern of light may comprise one or more lines.

The predetermined spot or pattern of light may comprise one or more crosses.

The predetermined spot or pattern of light may comprise a periodic pattern of light in one and/or two dimensions.

The predetermined spot or pattern of light may comprise a checkerboard pattern.

The predetermined spot or pattern of light may comprise a Hadamard pattern.

The predetermined spot or pattern of light may comprise one or symbols, letters and/or numerals.

Any of the VCSEL devices described above may be suitable for use in a mobile electronic device.

Any of the VCSEL devices described above may be suitable for use in laser range-finding, 3D sensing, 3D imaging, proximity sensing, environmental sensing, facial recognition, and eye tracking.

Any of the VCSEL devices described above may be suitable for use in an automobile.

Any of the VCSEL devices described above may be suitable for use in at least one of light detection and ranging (LIDAR), driver monitoring, gesture recognition and light projection.

Any of the VCSEL devices described above may be suitable for use in at least one of medical 3D imaging, pulse rate monitoring, and hair removal.

Any of the VCSEL devices described above may be suitable for use in at least one of industrial heating and additive manufacturing.

Any of the VCSEL devices described above may be suitable for use in illumination, for example for a surveillance camera.

Any of the VCSEL devices described above may be suitable for use in laser printing.

Any of the VCSEL devices described above may be suitable for use in computer mouse positioning.

Any of the VCSEL devices described above may be suitable for use in data communication, for example Li-Fi.

Any of the VCSEL devices described above may be suitable for use in an atomic clock.

According to an aspect of the present disclosure there is provided a mobile electronic device comprising a VCSEL device as described above for at least one of laser range-finding, 3D sensing, 3D imaging, proximity sensing, environmental sensing, facial recognition, and eye tracking.

According to an aspect of the present disclosure there is provided an automobile comprising a VCSEL device as described above for at least one of light detection and ranging (LIDAR), driver monitoring, gesture recognition and light projection.

According to an aspect of the present disclosure there is provided a plurality of VCSEL devices, each VCSEL device comprising any one of the VCSEL devices described above, wherein the plurality of VCSEL devices are formed, or monolithically integrated, on a common substrate. The plurality of VCSEL devices may be arranged in a 1D or 2D array such as a regular 1D or 2D array.

The spatial modulation region of each VCSEL device may define a corresponding outer surface which is directed away from the corresponding interior light generating region, and wherein the corresponding outer surface of the spatial modulation region of each VCSEL device has a corresponding uneven profile.

The profiles of the outer surfaces of the spatial modulation regions of at least two of the VCSEL devices may be the same.

The profiles of the outer surfaces of the spatial modulation regions of at least two of the VCSEL devices may be different. Consequently, two or more of the VCSEL devices may emit differently shaped beams even though the plurality of VCSEL devices are manufactured at the same time, for example using one or more lithographic processing steps.

The profile of the outer surface of the spatial modulation region of each VCSEL device may be configured so as to emit a corresponding shaped beam so that the plurality of VCSEL devices emit a plurality of shaped beams which combine, or which are superimposed, to provide a desired or predetermined beam pattern or light intensity distribution in the far field.

According to an aspect of the present disclosure there is provided a method for use in manufacturing a vertical cavity surface emitting laser (VCSEL) device, the VCSEL device comprising an exterior light emitting surface, and the method comprising:

monolithically integrating a spatial modulation region of the VCSEL device with an interior light generating region of the VCSEL device so that the spatial modulation region is located between the interior light generating region and the exterior light emitting surface,

wherein the spatial modulation region is configured to shape the light generated by the interior light generating region before emission from the exterior light emitting surface.

The interior light generating region, the spatial modulation region, and the exterior light emitting surface may be arranged along a VCSEL axis, and wherein the spatial modulation region may be configured to impose a transverse spatial modulation relative to the VCSEL axis on the light generated by the interior light generating region before the generated light is emitted from the exterior light emitting surface.

The spatial modulation region may be configured to impose a transverse spatial modulation in at least one of amplitude, phase and polarization on the light generated by the interior light generating region before the generated light is emitted from the exterior light emitting surface.

The method may comprise defining an outer surface of the spatial modulation region, which outer surface is directed away from the interior light generating region, and wherein the outer surface of the spatial modulation region has an uneven profile.

The method may comprise using lithography to define the outer surface of the spatial modulation region.

The method may comprise defining a plurality of diffractive element regions of the spatial modulation region, each diffractive element region defining a corresponding outer surface directed away from the interior light generating region, and each diffractive element region having a corresponding thickness measured in a direction parallel to the VCSEL axis so that the outer surface of each diffractive element region is located a corresponding distance from the interior light generating region measured in a direction parallel to the VCSEL axis, wherein the outer surfaces of the plurality of diffractive element regions together define the outer surface of the spatial modulation region.

The method may comprise defining the plurality of diffractive element regions of the spatial modulation region using lithography.

The thicknesses of at least two of the diffractive element regions may be different.

The thickness of each diffractive element region may be selected from a finite group of two or more different thicknesses.

The thickness of each diffractive element region may be selected from a group of 2^{N} different thicknesses, where N is the number of lithography masks used to manufacture the spatial modulation region.

The method may comprise defining the outer surface of the spatial modulation region using an imprinting, molding or stamping process. For example, the method may comprise defining the outer surface of the spatial modulation region by using a mold or a stamp such as a master mold or a master stamp to imprint, mold or stamp the outer surface of the spatial modulation region.

The method may comprise defining the outer surface of the spatial modulation region using a selective growth process such as atomic layer deposition.

The method may comprise monolithically integrating the interior light generating region and the spatial modulation region with a substrate so that the substrate is located between the interior light generating region and the exterior light emitting surface.

The method may comprise selecting a thickness of the substrate so that the VCSEL device emits a light beam of a predetermined size at the light emitting surface.

The method may comprise forming or monolithically integrating a plurality of VCSEL devices on a common substrate, wherein each VCSEL device comprises any one of the VCSEL devices described above.

The method may comprise forming a spatial modulation region of each VCSEL device so that the spatial modulation region of each VCSEL device defines a corresponding outer surface which is directed away from the corresponding interior light generating region, and wherein the corresponding outer surface of the spatial modulation region of each VCSEL device has a corresponding uneven profile.

The method may comprise forming the spatial modulation regions of at least two of the VCSEL devices so that the corresponding profiles of the outer surfaces of the spatial modulation regions may be the same.

The method may comprise forming the spatial modulation regions of at least two of the VCSEL devices so that the corresponding profiles of the outer surfaces of the spatial modulation regions may be different. Consequently, two or more of the VCSEL devices may emit differently shaped beams even though the plurality of VCSEL devices are manufactured at the same time, for example using one or more lithographic processing steps.

The method may comprise forming the spatial modulation region of each VCSEL device and the corresponding profile of the outer surface of the spatial modulation region so as to emit a corresponding shaped beam so that the plurality of VCSEL devices emit a plurality of shaped beams which combine, or which are superimposed, to provide a desired or predetermined beam pattern or light intensity distribution in the far field.

It should be understood that any one or more of the features of any one of the foregoing aspects of the present disclosure may be combined with any one or more of the features of any of the other foregoing aspects of the present disclosure.

### BRIEF DESCRIPTION OF THE DRAWINGS

Various VCSEL devices will now be described by way of non-limiting example only with reference to the following drawings of which:

FIG. 1A is a schematic of a vertical cavity surface emitting laser (VCSEL) device;

FIG. 1B is a schematic perspective view of the VCSEL device of FIG. 1A emitting a beam of light along a predetermined light emitting axis with a predetermined beam divergence;

FIG. 10 is a schematic side view of the VCSEL device of FIG. 1A emitting a beam of light along the predetermined light emitting axis with the predetermined beam divergence;

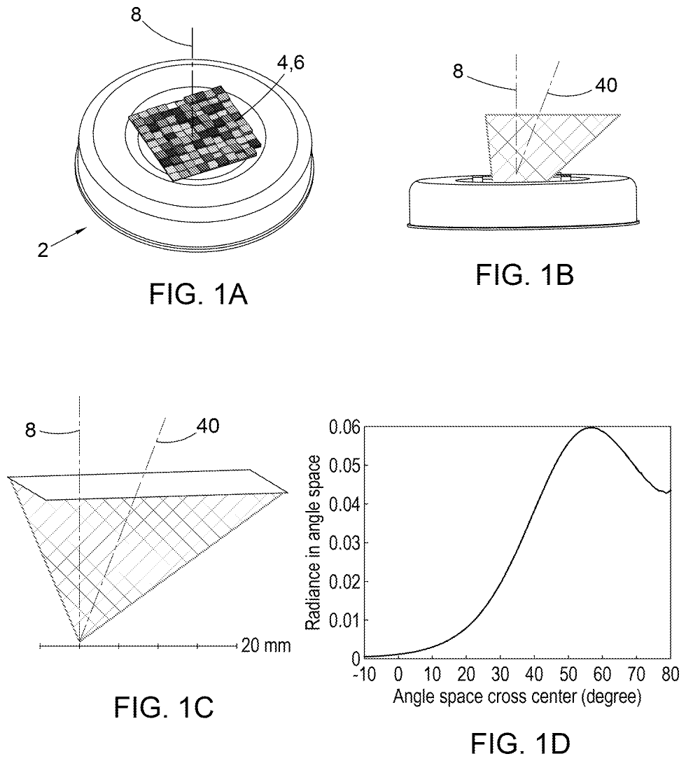

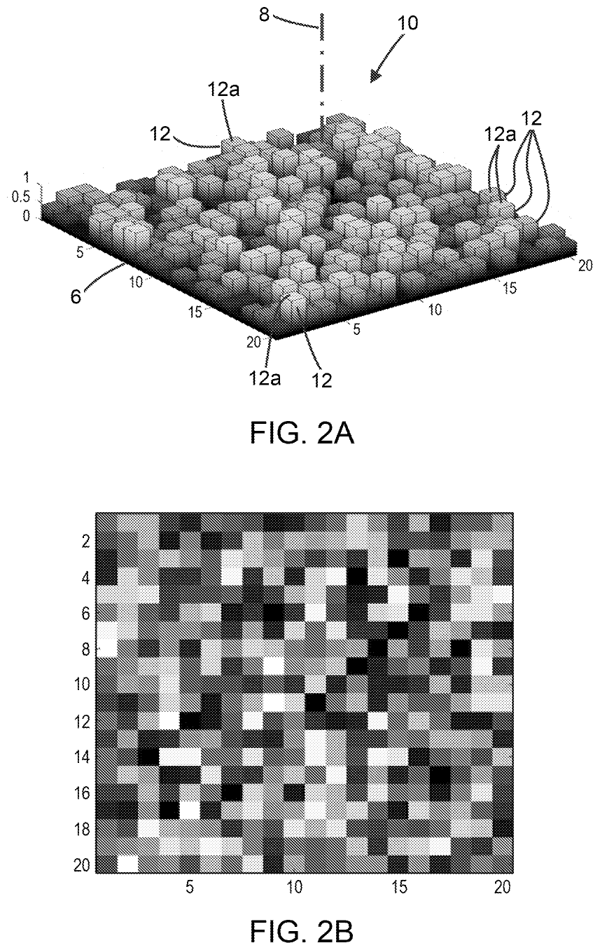

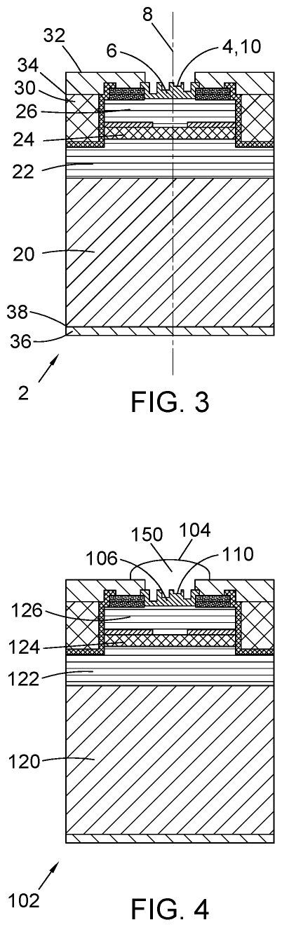

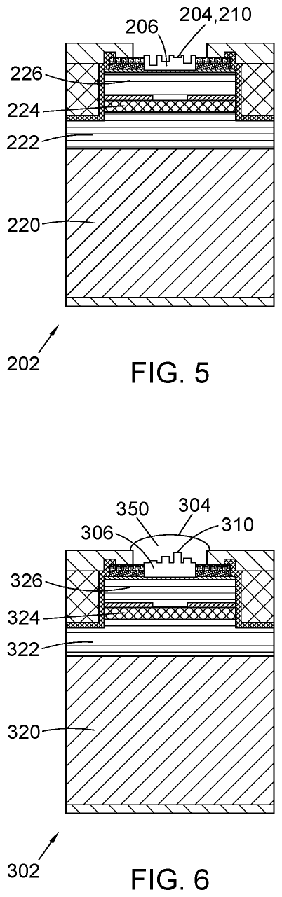

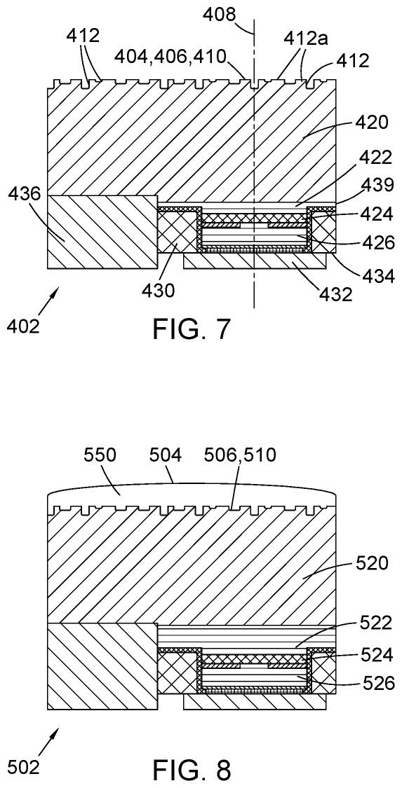

FIG. 1D is a plot of simulated intensity versus angle in degrees for a beam emitted from the VCSEL device of FIG. 1A;

FIG. 2A is a schematic of a spatial modulation region of the VCSEL device of FIG. 1A;

FIG. 2B is a representation of a transverse spatial modulation of the phase of a plurality of sublet wavefronts generated as a result of diffraction caused by a profile of an outer surface of the spatial modulation region shown in FIG. 2A;

FIG. 3 is a schematic cross-section of the top-emitting VCSEL device of FIG. 1A;

FIG. 4 is a schematic cross-section of a first alternative top-emitting VCSEL device;

FIG. 5 is a schematic cross-section of a second alternative top-emitting VCSEL device;

FIG. 6 is a schematic cross-section of a third alternative top-emitting VCSEL device;

FIG. 7 is a schematic cross-section of a bottom-emitting VCSEL device;

FIG. 8 is a schematic cross-section of a first alternative bottom-emitting VCSEL device;

FIG. 9 is a schematic cross-section of a second alternative bottom-emitting VCSEL device;

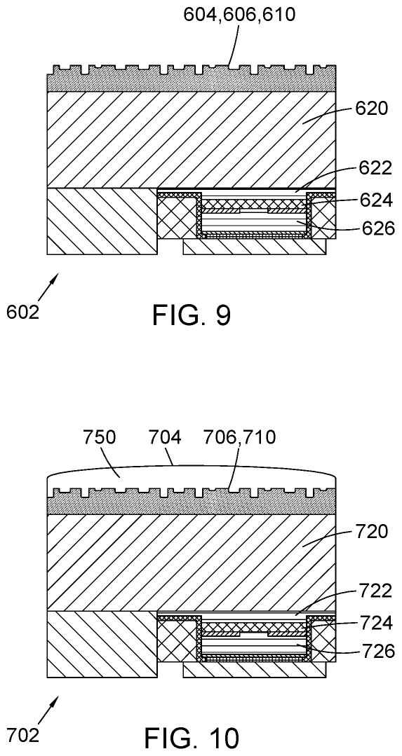

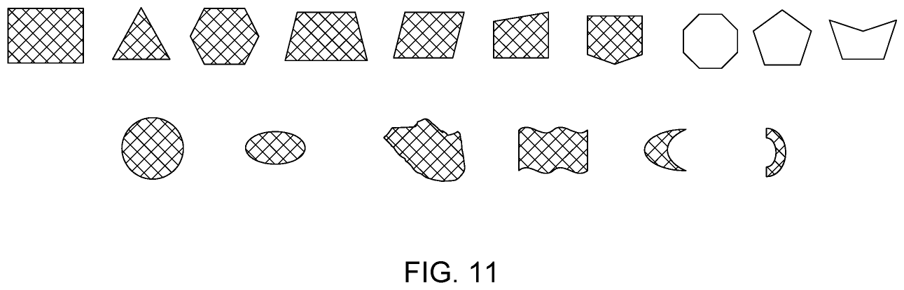

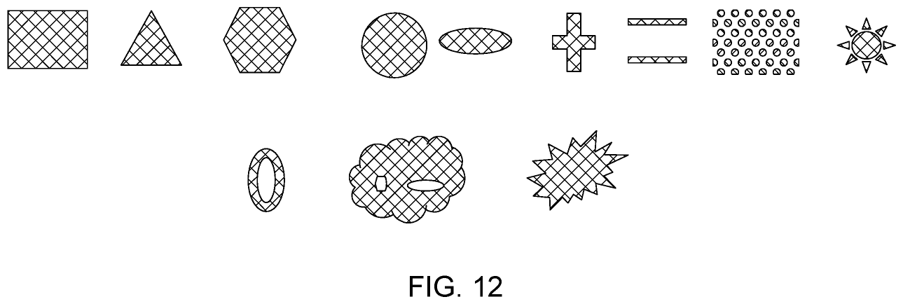

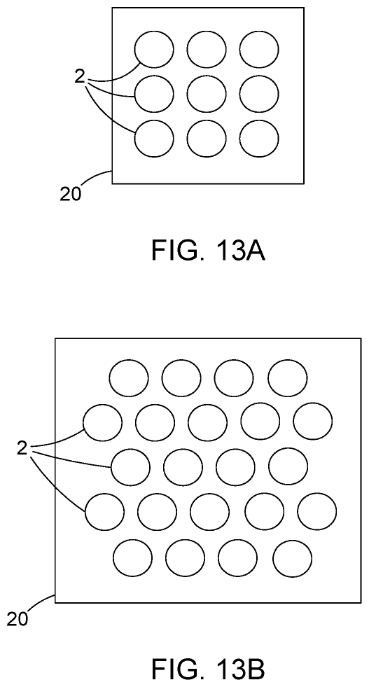

FIG. 10 is a schematic cross-section of a third alternative bottom-emitting VCSEL device;

FIG. 11 shows a variety of different configurations of an outer surface of a diffraction element region for use in a spatial modulation region of a VCSEL device;

FIG. 12 shows a variety of different spots or patterns of light that may be projected onto a surface when a VCSEL device emits a beam of light having a predetermined shape or structure transverse to a direction of propagation;

FIG. 13A is a schematic illustration of a first array of VCSEL devices; and

FIG. 13B is a schematic illustration of a second array of VCSEL devices.

### DETAILED DESCRIPTION OF THE DRAWINGS

Referring initially to FIG. 1A, there is shown a vertical cavity surface emitting laser (VCSEL) device generally designated 2 which includes an exterior light emitting surface 4 and a monolithically integrated spatial modulation region 6 which is configured to shape the light generated by an interior light generating region (not shown in FIG. 1A) before the generated light is emitted from the exterior light emitting surface 4.

As will be described in more detail below, the VCSEL device 2 defines a VCSEL axis 8, wherein the spatial modulation region 6 is configured to impose a transverse spatial modulation relative to the VCSEL axis 8 on the light generated by the interior light generating region before the generated light is emitted from the exterior light emitting surface 4. More specifically, the spatial modulation region 6 is configured to impose a transverse spatial modulation in at least one of amplitude, phase, and polarization on the light generated by the interior light generating region before the generated light is emitted from the exterior light emitting surface 4.

As shown in more detail in FIG. 2A, the spatial modulation region 6 defines an outer surface 10 having an uneven profile. More specifically, the spatial modulation region 6 defines a plurality of diffractive element regions 12, each diffractive element region 12 defining a corresponding outer surface 12a directed away from the interior light generating region (not shown in FIG. 2A), and each diffractive element region 12 having a corresponding thickness measured in a direction parallel to the VCSEL axis 8 so that the outer surface 12a of each diffractive element region 12 is located a corresponding distance from the interior light generating region measured in a direction parallel to the VCSEL axis 8, and wherein the outer surfaces 12a of the plurality of diffractive element regions 12 together define the outer surface 10 of the spatial modulation region 6, and wherein the thicknesses of at least two of the diffractive element regions 12 are different. More specifically, as shown in FIG. 2A, the thickness of each diffractive element region 12 is selected from a finite group of two or more different thicknesses. Moreover, one of ordinary skill in the art will understand that the outer surface 10 of the spatial modulation region 6 may be defined by one or more steps, each step comprising removing, for example etching, material from one or more of the outer surfaces 12a of one or more of the diffractive element regions 12. Moreover, the plurality of diffractive element regions 12 may be defined lithographically using one or more lithography masks, wherein the thickness of each diffractive element region 12 may be selected from a group of 2^{N} different thicknesses, where N is the number of lithography masks used to define the outer surface 10 of the spatial modulation region 6.

As shown in more detail in FIG. 3, the VCSEL device 2 further includes a substrate 20, a lower mirror structure 22, the interior light generating region 24 and an upper mirror structure 26, wherein the substrate 20, the lower mirror structure 22, the interior light generating region 24, the upper mirror structure 26, and the spatial modulation region 6 are all monolithically integrated with the lower mirror structure 22 being closer to the substrate 20 than the upper mirror structure 26, and the interior light generating region 24 being located between the lower and upper mirror structures 22, 26. The exterior light emitting surface 4 of the VCSEL device 2 is defined by the outer surface 10 of the spatial modulation region 6.

The substrate 20 is formed from gallium arsenide (GaAs). The interior light generating region 24 is formed from one or more layers of semiconductor material. Specifically, the interior light generating region 24 includes one or more quantum wells and a plurality of barriers, wherein each quantum well is located between two of the barriers. More specifically, the interior light generating region 24 includes one or more gallium arsenide (GaAs) quantum wells and a plurality of aluminium gallium arsenide (AlGaAs) barriers, wherein each gallium arsenide (GaAs) quantum well is located between two of the aluminium gallium arsenide (AlGaAs) barriers. The lower and upper mirror structures 22, 26 comprise distributed Bragg grating structures. The lower mirror structure 22, the interior light generating region 24, and the upper mirror structure 26 are grown epitaxially on the substrate 20. The lower mirror structure 22 and the upper mirror structure 26 each comprise a plurality of alternating aluminium gallium arsenide (AlGaAs) layers of different compositions i.e. alternating AlGaAs layers of different aluminium fractions. The thicknesses and compositions of the layers of the lower mirror structure 22 are selected so that the lower mirror structure 26 is highly reflective to light generated in the interior light generating region 24. The thicknesses and compositions of the layers of the upper mirror structure 26 are selected so that the upper mirror structure 26 is only partially reflective to light generated in the interior light generating region 24.

As may be appreciated from FIG. 3, the VCSEL device 2 is a top-emitting VCSEL device. Specifically, the VCSEL device 2 is configured to emit light in a direction away from the substrate 20. The interior light generating region 24 is located between the substrate 20 and the exterior light emitting surface 4. The upper mirror structure 26 is located between the interior light generating region 24 and the spatial modulation region 6. The spatial modulation region 6 is disposed on the upper mirror structure 26. The spatial modulation region 6 includes, or is formed from, a semiconductor material which is the same as a semiconductor material of which at least one of the substrate 20, the lower mirror structure 22, the interior light generating region 24, and the upper mirror structure 26 comprises. More specifically, the spatial modulation region 6 is formed from AlGaAs. The material of the spatial modulation region 6 is grown epitaxially on the upper mirror structure 26.

The VCSEL device 2 also includes a spacer region 30 which encircles the interior light generating region 24 and the upper mirror structure 26. The VCSEL device 2 further includes an upper electrode 32 formed, or deposited, on an upper surface 34 of the spacer region 30, and a lower electrode 36 formed, or deposited, on a lower surface 38 of the substrate 20.

In use, an electric current is passed between the upper and lower electrodes 32, 36 resulting in the generation of light in the interior light generating region 24 and amplification of the generated light in the interior light generating region 24 as the generated light is reflected between the lower and upper mirror structures 22, 26 through the interior light generating region 24. The upper mirror structure 26 transmits a portion of the light generated by the interior light generating region 24.

As a consequence of the uneven surface profile of the outer surface 10 of the spatial modulation region 6, the portion of the generated light which is transmitted by the upper mirror structure 26 is subject to transverse spatial modulation or diffraction as the portion of the generated light is transmitted through the spatial modulation region 6 and the exterior light emitting surface 4 of the VCSEL device 2 defined by the outer surface 10 of the spatial modulation region 6 to form an emitted beam of light. In effect, the outer surface 10 of the spatial modulation region 6 may be considered to comprise or define a diffractive optical region or a blazed diffraction grating for shaping the portion of the generated light which is transmitted by the upper mirror structure 26 before the light is emitted through the exterior light emitting surface 4 of the VCSEL device 2. More specifically, with reference to FIG. 2A, the plurality of diffractive element regions 12 break down a wavefront of the portion of the generated light which is transmitted by the upper mirror structure 26 into a plurality of spherical sublet wave fronts. The size and shape of each diffractive element region 12 is designed to vary an amplitude and phase of each sublet wavefront. For example, FIG. 2B shows the transverse spatial modulation of the phase of each of the sublet wavefronts resulting from diffraction at the outer surface of each of the diffractive element regions 12 that define the profile of the outer surface 10 shown in FIG. 2A. After transmission through the spatial modulation region 6 and the exterior light emitting surface 4 of the VCSEL device 2 defined by the outer surface 10 of the spatial modulation region 6, the sublet wavefronts travel coherently in space. A desired spatial distribution of light emitted from the VCSEL device 2 can be obtained by controlling the thicknesses of the different diffractive element regions 12 of the spatial modulation region 6 so as to control the profile of the outer surface 10 of the spatial modulation region 6 and the amplitude and phase of each of the sublet wavefronts. For example, a desired spatial distribution of light emitted from the VCSEL device 2 can be obtained in the far-field by controlling the thicknesses of the different diffractive element regions 12 of the spatial modulation region 6 so as to control the profile of the outer surface 10 of the spatial modulation region 6 and the amplitude and phase of each of the sublet wavefronts to provide a desired coherent superposition of the plurality of sublet wavefronts in the far-field.

For example, the spatial modulation region 6 may be configured so that the VCSEL device 2 emits a beam of light along a predetermined direction or light emitting axis, wherein the predetermined direction or light emitting axis defines a non-zero angle relative to the VCSEL axis 8 and/or the spatial modulation region 6 may be configured so that the VCSEL device 2 emits a beam of light having a predetermined beam divergence. For example, as shown in FIGS. 1B, 1C and 1D, the spatial modulation region 6 may be configured so that the VCSEL device 2 emits a beam of light along a predetermined direction or light emitting axis 40, wherein the predetermined direction or light emitting axis 40 defines an angle of approximately 50 degrees relative to the VCSEL axis 8 and the beam of light has a full-width half maximum (FWHM) beam divergence of approximately 60 degrees.

Referring now to FIG. 4 there is shown a first alternative top-emitting VCSEL device generally designated 102. As will be appreciated by one of ordinary skill in the art, the first alternative VCSEL device 102 includes many features which correspond to the features of the VCSEL device 2 of FIG. 3, with the features of the VCSEL device 102 of FIG. 4 being identified with the same reference numerals as the like features of the VCSEL device 2 of FIG. 3 incremented by ‘100’. Like the VCSEL device 2 of FIG. 3, the VCSEL device 102 of FIG. 4 includes a substrate 120, a lower mirror structure 122, an interior light generating region 124, an upper mirror structure 126 and a spatial modulation region 106, wherein the substrate 120, the lower mirror structure 122, the interior light generating region 124, the upper mirror structure 126, and the spatial modulation region 106 are all monolithically integrated with the lower mirror structure 122 being closer to the substrate 120 than the upper mirror structure 126, and the interior light generating region 124 being located between the lower and upper mirror structures 122, 126. However, unlike the VCSEL device 2 of FIG. 3, the VCSEL device 102 of FIG. 4 includes a silicon dioxide protective region in the form of encapsulation 150, wherein the encapsulation 150 covers the spatial modulation region 106, an outer surface of the encapsulation 150 defines an exterior light emitting surface 104 of the VCSEL device 102, and wherein the encapsulation 150 is configured for transmission of light generated by the interior light generating region 124. In use, the outer surface 110 of the spatial modulation region 106 may be considered to comprise or define a diffractive optical region or a blazed diffraction grating for shaping the portion of the generated light which is transmitted by the upper mirror structure 126. The encapsulation 150 may further shape the portion of the generated light which is transmitted by the upper mirror structure 126 before the light is emitted through the exterior light emitting surface 104 of the VCSEL device 102.

Referring now to FIG. 5 there is shown a second alternative top-emitting VCSEL device generally designated 202. As will be appreciated by one of ordinary skill in the art, the second alternative VCSEL device 202 includes many features which correspond to the features of the VCSEL device 2 of FIG. 3, with the features of the VCSEL device 202 of FIG. 5 being identified with the same reference numerals as the like features of the VCSEL device 2 of FIG. 3 incremented by ‘200’. Like the VCSEL device 2 of FIG. 3, the VCSEL device 202 of FIG. 5 includes a substrate 220, a lower mirror structure 222, an interior light generating region 224, an upper mirror structure 226 and a spatial modulation region 206, wherein the substrate 220, the lower mirror structure 222, the interior light generating region 224, the upper mirror structure 226, and the spatial modulation region 206 are all monolithically integrated with the lower mirror structure 222 being closer to the substrate 220 than the upper mirror structure 226, and the interior light generating region 224 being located between the lower and upper mirror structures 222, 226. However, unlike the VCSEL device 2 of FIG. 3, the VCSEL device 202 of FIG. 5, the spatial modulation region 206 is formed from a polymer material which is deposited on the upper mirror structure 226 and then processed to remove some of the polymer material from one or more selected areas of an outer surface of the polymer material so as to define an uneven outer surface 210 of the spatial modulation region 206. Consequently, an exterior light emitting surface 204 of the VCSEL device 202 is defined by the outer surface 210 of the spatial modulation region 206. In use, the outer surface 210 of the spatial modulation region 206 may be considered to comprise or define a diffractive optical region or a blazed diffraction grating for shaping the portion of the generated light which is transmitted by the upper mirror structure 226 before the light is emitted through the exterior light emitting surface 204 of the VCSEL device 202.

Referring now to FIG. 6 there is shown a third alternative top-emitting VCSEL device generally designated 302. As will be appreciated by one of ordinary skill in the art, the third alternative VCSEL device 302 includes many features which correspond to the features of the VCSEL device 202 of FIG. 5, with the features of the VCSEL device 302 of FIG. 6 being identified with the same reference numerals as the like features of the VCSEL device 202 of FIG. 5 incremented by ‘100’. Like the VCSEL device 202 of FIG. 5, the VCSEL device 302 of FIG. 6 includes a substrate 320, a lower mirror structure 322, an interior light generating region 324, an upper mirror structure 326 and a spatial modulation region 306, wherein the substrate 320, the lower mirror structure 322, the interior light generating region 324, the upper mirror structure 326, and the spatial modulation region 306 are all monolithically integrated with the lower mirror structure 322 being closer to the substrate 320 than the upper mirror structure 326, and the interior light generating region 324 being located between the lower and upper mirror structures 322, 326. However, unlike the VCSEL device 202 of FIG. 5, the VCSEL device 302 of FIG. 6 includes a silicon dioxide protective region in the form of encapsulation 350, wherein the encapsulation 350 covers the spatial modulation region 306, an outer surface of the encapsulation 350 defines an exterior light emitting surface 304 of the VCSEL device 302, and wherein the encapsulation 350 is configured for transmission of light generated by the interior light generating region 324. In use, the outer surface 310 of the spatial modulation region 306 may be considered to comprise or define a diffractive optical region or a blazed diffraction grating for shaping the portion of the generated light which is transmitted by the upper mirror structure 326. The encapsulation 350 may further shape the portion of the generated light which is transmitted by the upper mirror structure 326 before the light is emitted through the exterior light emitting surface 304 of the VCSEL device 302.

Referring now to FIG. 7 there is shown a bottom-emitting VCSEL device generally designated 402. As will be appreciated by one of ordinary skill in the art, the VCSEL device 402 includes many features which correspond to the features of the VCSEL device 2 of FIG. 3, with the features of the VCSEL device 402 of FIG. 7 being identified with the same reference numerals as the like features of the VCSEL device 2 of FIG. 3 incremented by ‘400’. Like the VCSEL device 2 of FIG. 3, the VCSEL device 402 of FIG. 7 includes a substrate 420, a lower mirror structure 422, an interior light generating region 424, an upper mirror structure 426, wherein the substrate 420, the lower mirror structure 422, the interior light generating region 424, and the upper mirror structure 426 are all monolithically integrated with the lower mirror structure 422 being closer to the substrate 420 than the upper mirror structure 426, and the interior light generating region 424 being located between the lower and upper mirror structures 422, 426. The lower mirror structure 422, the interior light generating region 424, and the upper mirror structure 426 are located to a first side of the substrate 420. Specifically, the lower mirror structure 422, the interior light generating region 424, and the upper mirror structure 426 are grown epitaxially on the first side of the substrate 420. However, unlike the VCSEL device 2 of FIG. 3, in the VCSEL device 402 of FIG. 7, a second side of the substrate 420, opposite to the first side of the substrate 420, defines a spatial modulation region 406, wherein the spatial modulation region 406 has an outer surface 410 having an uneven profile which defines an exterior light emitting surface 404 of the VCSEL device 402.

More specifically, the spatial modulation region 406 defines a plurality of diffractive element regions 412, each diffractive element region 412 defining a corresponding outer surface 412a directed away from the interior light generating region 424, and each diffractive element region 412 having a corresponding thickness measured in a direction parallel to the VCSEL axis 408 so that the outer surface 412a of each diffractive element region 412 is located a corresponding distance from the interior light generating region 424 measured in a direction parallel to the VCSEL axis 408, and wherein the outer surfaces 412a of the plurality of diffractive element regions 412 together define the outer surface 410 of the spatial modulation region 406, and wherein the thicknesses of at least two of the diffractive element regions 412 are different. More specifically, the thickness of each diffractive element region 412 is selected from a finite group of two or more different thicknesses. Moreover, one of ordinary skill in the art will understand that the outer surface 410 of the spatial modulation region 406 may be defined by one or more steps, each step comprising removing, for example etching, material from one or more of the outer surfaces 412a of one or more of the diffractive element regions 412. Moreover, the plurality of diffractive element regions 412 may be defined lithographically using one or more lithography masks, wherein the thickness of each diffractive element region 412 may be selected from a group of 2^{N} different thicknesses, where N is the number of lithography masks used to define the outer surface 410 of the spatial modulation region 406.

The substrate 420 is formed from gallium arsenide (GaAs). The interior light generating region 424 is formed from one or more layers of semiconductor material. Specifically, the interior light generating region 424 includes one or more quantum wells and a plurality of barriers, wherein each quantum well is located between two of the barriers. More specifically, the interior light generating region 424 includes one or more indium gallium arsenide (InGaAs) quantum wells and a plurality of gallium arsenide (GaAs) barriers, wherein each indium gallium arsenide (InGaAs) quantum well is located between two of the gallium arsenide (GaAs) barriers. The lower and upper mirror structures 422, 426 comprise distributed Bragg grating structures. The lower mirror structure 422, the interior light generating region 424, and the upper mirror structure 426 are grown epitaxially on the substrate 420. The lower mirror structure 422 and the upper mirror structure 426 each comprise a plurality of alternating layers of different compositions e.g. alternating layers of indium gallium arsenide (InGaAs) of different compositions or alternating layers of indium gallium arsenide (InGaAs) and gallium arsenide (GaAs). The thicknesses and compositions of the layers of the lower mirror structure 422 are selected so that the lower mirror structure 426 is only partially reflective to light generated in the interior light generating region 424. The thicknesses and compositions of the layers of the upper mirror structure 426 are selected so that the upper mirror structure 426 is highly reflective to light generated in the interior light generating region 424.

The VCSEL device 402 also includes a spacer region 430 which encircles the interior light generating region 424 and the upper mirror structure 426. The VCSEL device 402 further includes a first electrode 432 formed, or deposited, on an upper surface 434 of the spacer region 430, and a second electrode 436 formed, or deposited, on an upper surface 439 of the substrate 420.

In use, an electric current is passed between the first and second electrodes 432, 436 resulting in the generation of light in the interior light generating region 424 and amplification of the generated light in the interior light generating region 424 as the generated light is reflected between the lower and upper mirror structures 422, 426 through the interior light generating region 424. The lower mirror structure 422 transmits a portion of the light generated by the interior light generating region 424. The portion of the light generated by the interior light generating region 424 that is transmitted by the lower mirror structure 422 is subsequently transmitted by the substrate 420.

As a consequence of the uneven surface profile of the outer surface 410 of the spatial modulation region 406, the portion of the generated light which is transmitted by the lower mirror structure 422 is subject to transverse spatial modulation or diffraction as the portion of the generated light is transmitted through the spatial modulation region 406 and the exterior light emitting surface 404 of the VCSEL device 402 defined by the outer surface 410 of the spatial modulation region 406 to form an emitted beam of light. In effect, the outer surface 410 of the spatial modulation region 406 may be considered to comprise or define a diffractive optical region or a blazed diffraction grating for shaping the portion of the generated light which is transmitted by the lower mirror structure 422 before the light is emitted through the exterior light emitting surface 404 of the VCSEL device 402.

Referring now to FIG. 8 there is shown a first alternative bottom-emitting VCSEL device generally designated 502. As will be appreciated by one of ordinary skill in the art, the VCSEL device 502 includes many features which correspond to the features of the VCSEL device 402 of FIG. 7, with the features of the VCSEL device 502 of FIG. 8 being identified with the same reference numerals as the like features of the VCSEL device 402 of FIG. 7 incremented by ‘100’. Like the VCSEL device 402 of FIG. 7, the VCSEL device 502 of FIG. 8 includes a substrate 520, a partially reflecting lower mirror structure 522, an interior light generating region 524, a highly reflecting upper mirror structure 526, wherein the substrate 520, the lower mirror structure 522, the interior light generating region 524, and the upper mirror structure 526 are all monolithically integrated with the lower mirror structure 522 being closer to the substrate 520 than the upper mirror structure 526, and the interior light generating region 524 being located between the lower and upper mirror structures 522, 526. The lower mirror structure 522, the interior light generating region 524, and the upper mirror structure 526 are located to a first side of the substrate 520. Specifically, the lower mirror structure 522, the interior light generating region 524, and the upper mirror structure 526 are grown epitaxially on the first side of the substrate 520. A second side of the substrate 520, opposite to the first side of the substrate 520, defines a spatial modulation region 506, wherein the spatial modulation region 506 has an outer surface 510 having an uneven profile which defines an exterior light emitting surface 504 of the VCSEL device 502. However, unlike the VCSEL device 402 of FIG. 7, the VCSEL device 502 of FIG. 8 includes a silicon dioxide protective region in the form of encapsulation 550, wherein the encapsulation 550 covers the spatial modulation region 506, an outer surface of the encapsulation 550 defines an exterior light emitting surface 504 of the VCSEL device 502, and wherein the encapsulation 550 is configured for transmission of light generated by the interior light generating region 524. In use, the outer surface 510 of the spatial modulation region 506 may be considered to comprise or define a diffractive optical region or a blazed diffraction grating for shaping the portion of the generated light which is transmitted by the lower mirror structure 522. The encapsulation 550 may further shape the portion of the generated light which is transmitted by the lower mirror structure 522 before the light is emitted through the exterior light emitting surface 504 of the VCSEL device 502.

Referring now to FIG. 9 there is shown a second alternative bottom-emitting VCSEL device generally designated 602. As will be appreciated by one of ordinary skill in the art, the VCSEL device 602 includes many features which correspond to the features of the VCSEL device 402 of FIG. 7, with the features of the VCSEL device 602 of FIG. 9 being identified with the same reference numerals as the like features of the VCSEL device 402 of FIG. 7 incremented by ‘200’. Like the VCSEL device 402 of FIG.

7, the VCSEL device 602 of FIG. 9 includes a substrate 620, a partially reflecting lower mirror structure 622, an interior light generating region 624, and a highly reflecting upper mirror structure 626, wherein the substrate 620, the lower mirror structure 622, the interior light generating region 624, and the upper mirror structure 626 are all monolithically integrated with the lower mirror structure 622 being closer to the substrate 620 than the upper mirror structure 626, and the interior light generating region 624 being located between the lower and upper mirror structures 622, 626. The lower mirror structure 622, the interior light generating region 624, and the upper mirror structure 626 are located to a first side of the substrate 620. Specifically, the lower mirror structure 622, the interior light generating region 624, and the upper mirror structure 626 are grown epitaxially on the first side of the substrate 620. However, unlike the VCSEL device 402 of FIG. 7, the VCSEL device 602 of FIG. 9 includes additional material which is monolithically integrated with the substrate 620. Specifically, the additional material is grown epitaxially or deposited on a second side of the substrate 620 opposite to the first side of the substrate 620, and a spatial modulation region 606 is defined in an outer surface 610 of the additional material so that the outer surface 610 of the additional material has an uneven profile which defines an exterior light emitting surface 604 of the VCSEL device 602. For example, the additional material may comprise a polymer material. In use, the outer surface 610 of the spatial modulation region 606 may be considered to comprise or define a diffractive optical region or a blazed diffraction grating for shaping the portion of the generated light which is transmitted by the lower mirror structure 622 before the light is emitted through the exterior light emitting surface 604 of the VCSEL device 602.

Referring now to FIG. 10 there is shown a third alternative bottom-emitting VCSEL device generally designated 702. As will be appreciated by one of ordinary skill in the art, the VCSEL device 702 includes many features which correspond to the features of the VCSEL device 602 of FIG. 9, with the features of the VCSEL device 702 of FIG. 10 being identified with the same reference numerals as the like features of the VCSEL device 602 of FIG. 9 incremented by ‘100’. Like the VCSEL device 602 of FIG. 9, the VCSEL device 702 of FIG. 10 includes a substrate 720, a partially reflecting lower mirror structure 722, an interior light generating region 724, and a highly reflecting upper mirror structure 726, wherein the substrate 720, the lower mirror structure 722, the interior light generating region 724, and the upper mirror structure 726 are all monolithically integrated with the lower mirror structure 722 being closer to the substrate 720 than the upper mirror structure 726, and the interior light generating region 724 being located between the lower and upper mirror structures 722, 726. The lower mirror structure 722, the interior light generating region 724, and the upper mirror structure 726 are located to a first side of the substrate 720. Specifically, the lower mirror structure 722, the interior light generating region 724, and the upper mirror structure 726 are grown epitaxially on the first side of the substrate 720. The VCSEL device 702 also includes additional material which is monolithically integrated with the substrate 720. Specifically, the additional material is grown epitaxially or deposited on a second side of the substrate 720 opposite to the first side of the substrate 720, and a spatial modulation region 706 is defined in an outer surface 710 of the additional material so that the outer surface 710 of the additional material has an uneven profile.

For example, the additional material may comprise a polymer material. However, unlike the VCSEL device 602 of FIG. 9, the VCSEL device 702 of FIG. 10 includes a silicon dioxide protective region in the form of encapsulation 750, wherein the encapsulation 750 covers the spatial modulation region 706, an outer surface of the encapsulation 750 defines an exterior light emitting surface 704 of the VCSEL device 702, and wherein the encapsulation 750 is configured for transmission of light generated by the interior light generating region 724. In use, the outer surface 710 of the spatial modulation region 706 may be considered to comprise or define a diffractive optical region or a blazed diffraction grating for shaping the portion of the generated light which is transmitted by the lower mirror structure 722. The encapsulation 750 may further shape the portion of the generated light which is transmitted by the lower mirror structure 722 before the light is emitted through the exterior light emitting surface 704 of the VCSEL device 702.

One of ordinary skill in the art will understand that the spatial modulation region of any of the VCSEL devices described above may be configured differently according to a beam shape requirement. For example, the spatial modulation region of any of the VCSEL devices described above may define a plurality of diffraction element regions, wherein any of the diffraction element regions have an outer surface having any of the shapes shown in FIG. 11. Additionally or alternatively, the spatial modulation region of any of the VCSEL devices described above may be configured so that the VCSEL device emits a beam of light having a predetermined shape or structure transverse to a direction of propagation so that the beam of light forms a predetermined spot or pattern of light when projected onto a surface. For example, the spatial modulation region of any of the VCSEL devices described above may be configured so that the VCSEL device emits a beam of light having a predetermined shape or structure transverse to a direction of propagation so that the beam of light forms any of the predetermined spot or pattern of light shown in FIG. 12 when projected onto a surface. The predetermined spot or pattern of light may comprise one or more predetermined shapes. The predetermined spot or pattern of light may comprise one or more triangles, quadrilaterals, and/or polygons. The predetermined spot or pattern of light may comprise one or more spots or dots. The predetermined spot or pattern of light may comprise one or more circular or elliptical shapes. The predetermined spot or pattern of light may comprise one or more rings. The predetermined spot or pattern of light may comprise one or more lines. The predetermined spot or pattern of light may comprise one or more crosses. The predetermined spot or pattern of light may comprise a periodic pattern of light in one and/or two dimensions. The predetermined spot or pattern of light may comprise a checkerboard pattern. The predetermined spot or pattern of light may comprise a Hadamard pattern. The predetermined spot or pattern of light may comprise one or symbols, letters and/or numerals.

Referring now to FIG. 13A, there is shown a plurality of VCSEL devices 2, wherein the VCSEL devices are formed on a common substrate 20 and are arranged in a regular 3×3 array. The spatial modulation region 6 of each VCSEL device 2 may define a corresponding outer surface 10 which is directed away from the corresponding interior light generating region 24, and wherein the corresponding outer surface 10 of the spatial modulation region 6 of each VCSEL device 2 has a corresponding uneven profile. The profiles of the outer surfaces 10 of the spatial modulation regions 6 of at least two of the VCSEL devices 2 may be the same. The profiles of the outer surfaces 10 of the spatial modulation regions 6 of at least two of the VCSEL devices 2 may be different. Consequently, two or more of the VCSEL devices 2 may emit differently shaped beams even though the plurality of VCSEL devices 2 are manufactured at the same time, for example using one or more lithographic processing steps.

Referring now to FIG. 13B, there is shown a plurality of VCSEL devices 2, wherein the VCSEL devices are formed on a common substrate 20 and are arranged in a hexagonal close packed array. The spatial modulation region 6 of each VCSEL device 2 may define a corresponding outer surface 10 which is directed away from the corresponding interior light generating region 24, and wherein the corresponding outer surface 10 of the spatial modulation region 6 of each VCSEL device 2 has a corresponding uneven profile. The profiles of the outer surfaces 10 of the spatial modulation regions 6 of at least two of the VCSEL devices 2 may be the same. The profiles of the outer surfaces 10 of the spatial modulation regions 6 of at least two of the VCSEL devices 2 may be different. Consequently, two or more of the VCSEL devices 2 may emit differently shaped beams even though the plurality of VCSEL devices 2 are manufactured at the same time, for example using one or more lithographic processing steps.

One of ordinary skill in the art will understand that rather than the plurality of VCSEL devices comprising a plurality of the VCSEL devices 2 described with reference to FIGS. 1A-3, the plurality of VCSEL devices may comprise a plurality of any of the VCSEL devices described with reference to any of FIGS. 3-12 wherein the VCSEL devices are formed on a common substrate. The profiles of the outer surfaces of the spatial modulation regions of at least two of the VCSEL devices may be the same. The profiles of the outer surfaces of the spatial modulation regions of at least two of the VCSEL devices may be different. Additionally or alternatively, the VCSEL devices may be arranged in a 1D array or a 2D array of any size. The VCSEL devices may be arranged in a regular 1D array or a regular 2D array.

The profile of the outer surface of the spatial modulation region of each VCSEL device may be configured so as to emit a corresponding shaped beam so that the plurality of VCSEL devices emit a plurality of shaped beams which combine, or which are superimposed, to provide a desired or predetermined beam pattern or light intensity distribution in the far field.

Various modifications are possible to the VCSEL devices described above. For example, rather than the spatial modulation regions 206, 306, 606, 706 comprising a polymer material as described with reference to FIGS. 5, 6, 9 and 10 respectively, the spatial modulation region may comprise a dielectric material.

Rather than the VCSEL device including a protective region or encapsulation comprising silicon dioxide as described with reference to FIGS. 4, 6, 8 and 10, the protective region may comprise silicon nitride or a polymer.

Rather than the outer surface of the spatial modulation region being formed by lithography and etching, the outer surface of the spatial modulation region may be formed by an imprinting, molding or stamping process. For example, the outer surface of the spatial modulation region may be formed using a mold or a stamp such as a master mold or a master stamp. Alternatively, the outer surface of the spatial modulation region may be formed using a selective growth process such as atomic layer deposition.

Each diffractive element region of the spatial modulation region may adjoin, or be contiguous with, at least one adjacent diffractive element region of the spatial modulation region.

Each diffractive element region may be configured so that the outer surfaces of the plurality of diffractive element regions achieve a 100% fill factor of the outer surface of the spatial modulation region. For example, each diffractive element region may have an outer surface of any shape and/or size so that the outer surfaces of the plurality of diffractive element regions achieve a 100% fill factor of the outer surface of the spatial modulation region. Two or more of the diffractive element regions may have outer surfaces having the same shape and/or size. Two or more of the diffractive element regions may have outer surfaces having different shapes and/or sizes.

At least two of the outer surfaces of the diffractive element regions may be triangular, quadrilateral, square, rectangular, or hexagonal in shape.

The outer surfaces of all of the diffractive element regions may have the same shape and size.

At least two of the outer surfaces of the diffractive element regions may have different shapes and/or sizes.

The outer surfaces of the diffractive element regions may have a minimum feature size of 0.5 μm or less, 0.2 μm or less, or 0.1 μm or less.

A method for use in manufacturing a vertical cavity surface emitting laser (VCSEL) device with an exterior light emitting surface, may comprise:

monolithically integrating a spatial modulation region of the VCSEL device with an interior light generating region of the VCSEL device so that the spatial modulation region is located between the interior light generating region and the exterior light emitting surface,

wherein the spatial modulation region is configured to shape the light generated by the interior light generating region before emission from the exterior light emitting surface.

The interior light generating region, the spatial modulation region, and the exterior light emitting surface may be arranged along a VCSEL axis, and wherein the spatial modulation region may be configured to impose a transverse spatial modulation relative to the VCSEL axis on the light generated by the interior light generating region before the generated light is emitted from the exterior light emitting surface.

The spatial modulation region may be configured to impose a transverse spatial modulation in at least one of amplitude, phase and polarization on the light generated by the interior light generating region before the generated light is emitted from the exterior light emitting surface.

The method may comprise defining an outer surface of the spatial modulation region, which outer surface is directed away from the interior light generating region, and wherein the outer surface of the spatial modulation region has an uneven profile.

The method may comprise using lithography to define the outer surface of the spatial modulation region.

The method may comprise defining a plurality of diffractive element regions of the spatial modulation region, each diffractive element region defining a corresponding outer surface directed away from the interior light generating region, and each diffractive element region having a corresponding thickness measured in a direction parallel to the VCSEL axis so that the outer surface of each diffractive element region is located a corresponding distance from the interior light generating region measured in a direction parallel to the VCSEL axis, wherein the outer surfaces of the plurality of diffractive element regions together define the outer surface of the spatial modulation region.

The method may comprise using lithography to define the plurality of diffractive element regions of the spatial modulation region.

The thicknesses of at least two of the diffractive element regions may be different.

The thickness of each diffractive element region may be selected from a finite group of two or more different thicknesses.

The thickness of each diffractive element region may be selected from a group of 2^{N} different thicknesses, where N is the number of lithography masks used to manufacture the spatial modulation region.

The method may comprise defining the outer surface of the spatial modulation region using an imprinting, molding or stamping process. For example, the method may comprise defining the outer surface of the spatial modulation region by using a mold or a stamp such as a master mold or a master stamp to imprint, mold or stamp the outer surface of the spatial modulation region.

The method may comprise defining the outer surface of the spatial modulation region using a selective growth process such as atomic layer deposition.

The method may comprise manufacturing any of the bottom-emitting vertical cavity surface emitting laser (VCSEL) devices of any of FIGS. 7-10 by monolithically integrating the interior light generating region and the spatial modulation region with the substrate so that the substrate is located between the interior light generating region and the exterior light emitting surface.

The method may comprise selecting a thickness of the substrate of any of the bottom-emitting vertical cavity surface emitting laser (VCSEL) devices of any of FIGS. 7-10 so that the VCSEL device emits a light beam of a predetermined size at the light emitting surface.

The method may comprise forming or monolithically integrating a plurality of VCSEL devices on a common substrate, wherein each VCSEL device comprises any one of the VCSEL devices described above.

The method may comprise forming a spatial modulation region of each VCSEL device so that the spatial modulation region of each VCSEL device defines a corresponding outer surface which is directed away from the corresponding interior light generating region, and wherein the corresponding outer surface of the spatial modulation region of each VCSEL device has a corresponding uneven profile.

The method may comprise forming the spatial modulation regions of at least two of the VCSEL devices so that the corresponding profiles of the outer surfaces of the spatial modulation regions may be the same.

The method may comprise forming the spatial modulation regions of at least two of the VCSEL devices so that the corresponding profiles of the outer surfaces of the spatial modulation regions may be different. Consequently, two or more of the VCSEL devices may emit differently shaped beams even though the plurality of VCSEL devices are manufactured at the same time, for example using one or more lithographic processing steps.

The method may comprise forming the spatial modulation region of each VCSEL device and the corresponding profile of the outer surface of the spatial modulation region so as to emit a corresponding shaped beam so that the plurality of VCSEL devices emit a plurality of shaped beams which combine, or which are superimposed, to provide a desired or predetermined beam pattern or light intensity distribution in the far field.

### LIST OF REFERENCE NUMERALS

2 VCSEL device;

4 exterior light emitting surface;

6 spatial modulation region;

8 VCSEL axis;

10 outer surface of spatial modulation region;

12 diffractive element region of spatial modulation region;

12a outer surface of a diffractive element region;

20 substrate;

22 lower mirror structure;

24 interior light generating region;

26 upper mirror structure;

30 spacer region;

32 upper electrode;

34 upper surface of spacer region;

36 lower electrode;

38 lower surface of substrate;

40 light emitting axis;

102 VCSEL device;

104 exterior light emitting surface;

106 spatial modulation region;

110 outer surface of spatial modulation region;

120 substrate;

122 lower mirror structure;

124 interior light generating region;

126 upper mirror structure;

150 encapsulation;

202 VCSEL device;

204 exterior light emitting surface;

206 spatial modulation region;

210 outer surface of spatial modulation region;

220 substrate;

222 lower mirror structure;

224 interior light generating region;

226 upper mirror structure;

302 VCSEL device;

304 exterior light emitting surface;

306 spatial modulation region;

310 outer surface of spatial modulation region;

320 substrate;

322 lower mirror structure;

324 interior light generating region;

326 upper mirror structure;

350 encapsulation;

402 VCSEL device;

404 exterior light emitting surface;

406 spatial modulation region;

408 VCSEL axis;

410 outer surface of spatial modulation region;

412 diffractive element region of spatial modulation region;

412a outer surface of a diffractive element region;

420 substrate;

422 lower mirror structure;

424 interior light generating region;

426 upper mirror structure;

430 spacer region;

432 first electrode;

434 upper surface of spacer region;

436 second electrode;

439 upper surface of substrate;

502 VCSEL device;

504 exterior light emitting surface;

506 spatial modulation region;

510 outer surface of spatial modulation region;

520 substrate;

522 lower mirror structure;

524 interior light generating region;

526 upper mirror structure;

550 encapsulation;

602 VCSEL device;

604 exterior light emitting surface;

606 spatial modulation region;

610 outer surface of spatial modulation region;

620 substrate;

622 lower mirror structure;

624 interior light generating region;

626 upper mirror structure;

702 VCSEL device;

704 exterior light emitting surface;

706 spatial modulation region;

710 outer surface of spatial modulation region;

720 substrate;

722 lower mirror structure;

724 interior light generating region;

726 upper mirror structure; and

750 encapsulation.

One of ordinary skill in the art will understand that in the preceding description and appended claims, positional terms such as ‘above’, ‘along’, ‘side’, etc. are made with reference to conceptual illustrations, such as those shown in the appended drawings. These terms are used for ease of reference but are not intended to be of limiting nature. These terms are therefore to be understood as referring to an object when in an orientation as shown in the accompanying drawings.

One of ordinary skill in the art will understand that one or more of the features of the embodiments of the present disclosure described above with reference to the drawings may produce effects or provide advantages when used in isolation from one or more of the other features of the embodiments of the present disclosure and that different combinations of the features are possible other than the specific combinations of the features of the embodiments of the present disclosure described above.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in any embodiment, whether alone or in any appropriate combination with any other feature disclosed or illustrated herein.

1. A vertical cavity surface emitting laser (VCSEL) device comprising:
an interior light generating region;
an exterior light emitting surface; and
a spatial modulation region monolithically integrated with the interior light generating region so that the spatial modulation region is located between the interior light generating region and the exterior light emitting surface,
wherein the spatial modulation region is configured to shape the light generated by the interior light generating region before the generated light is emitted from the exterior light emitting surface.

2. A VCSEL device as claimed in claim 1, wherein the interior light generating region, the spatial modulation region, and the exterior light emitting surface are arranged along a VCSEL axis, and wherein the spatial modulation region is configured to impose a transverse spatial modulation relative to the VCSEL axis on the light generated by the interior light generating region before the generated light is emitted from the exterior light emitting surface.

3. A VCSEL device as claimed in claim 1, wherein the spatial modulation region is configured to impose a transverse spatial modulation in at least one of amplitude, phase, and polarization on the light generated by the interior light generating region before the generated light is emitted from the exterior light emitting surface.

4. A VCSEL device as claimed in claim 1, wherein the spatial modulation region defines an outer surface which is directed away from the interior light generating region, and wherein the outer surface of the spatial modulation region has an uneven profile.

5. A VCSEL device as claimed in claim 4, wherein the spatial modulation region defines a plurality of diffractive element regions, each diffractive element region defining a corresponding outer surface directed away from the interior light generating region, and each diffractive element region having a corresponding thickness measured in a direction parallel to the VCSEL axis so that the outer surface of each diffractive element region is located a corresponding distance from the interior light generating region measured in a direction parallel to the VCSEL axis, and wherein the outer surfaces of the plurality of diffractive element regions together define the outer surface of the spatial modulation region, and wherein the thicknesses of at least two of the diffractive element regions are different.

6. A VCSEL device as claimed in claim 5, wherein the thickness of each diffractive element region is selected from a finite group of two or more different thicknesses.

7. A VCSEL device as claimed in claim 5, wherein at least one of:
the outer surface of the spatial modulation region is defined by one or more steps, each step comprising removing, for example etching, material from one or more of the outer surfaces of the diffractive element regions, wherein the one or more diffractive element regions are defined lithographically using one or more lithography masks, and wherein the thickness of each diffractive element region is selected from a group of 2^{N} different thicknesses, where N is the number of lithography masks used to define the outer surface of the spatial modulation region;
the outer surface of the spatial modulation region is formed by an imprinting, molding or stamping process; and
the outer surface of the spatial modulation region is formed using a selective growth process such as atomic layer deposition.

8. A VCSEL device as claimed in claim 5, wherein at least one of:
each diffractive element region of the spatial modulation region adjoins, or is contiguous with, at least one adjacent diffractive element region of the spatial modulation region;
each diffractive element region is configured so that the outer surfaces of the plurality of diffractive element regions achieve a 100% fill factor of the outer surface of the spatial modulation region;
each diffractive element region has an outer surface of any shape and/or size so that the outer surfaces of the plurality of diffractive element regions achieve a 100% fill factor of the outer surface of the spatial modulation region;
two or more of the diffractive element regions have outer surfaces having the same shape and/or size;
two or more of the diffractive element regions have outer surfaces having different shapes and/or sizes; and
at least two of the outer surfaces of the diffractive element regions are triangular, quadrilateral, square, rectangular, or hexagonal in shape.

9. A VCSEL device as claimed in any one of claims d to 9claim 4, wherein the exterior light emitting surface is defined by the outer surface of the spatial modulation region.

10. A VCSEL device as claimed in claim 4, comprising a protective region which covers the spatial modulation region and which defines the exterior light emitting surface, wherein the protective region is configured for transmission of light generated by the interior light generating region.

11. A VCSEL device as claimed in claim 1, comprising:
a substrate;
a lower mirror structure; and
an upper mirror structure,
wherein the substrate, the lower mirror structure, the interior light generating region, the upper mirror structure, and the spatial modulation region are all monolithically integrated,
wherein the lower mirror structure is closer to the substrate than the upper mirror structure, and the interior light generating region is located between the lower and upper mirror structures, and
wherein at least one of:
the VCSEL device is configured to emit light in a direction away from the substrate;
the interior light generating region is located between the substrate and the exterior light emitting surface; and
the upper mirror structure is located between the interior light generating region and the spatial modulation region.

12. A VCSEL device as claimed in claim 11, wherein the material of the spatial modulation region is grown epitaxially on the upper mirror structure.

13. A VCSEL device as claimed in claim 12, wherein the material of the spatial modulation region is deposited on the upper mirror structure and/or wherein the spatial modulation region comprises a polymer material and/or a dielectric material.

14. A VCSEL device as claimed in claim 1, comprising:
a substrate;
a lower mirror structure; and
an upper mirror structure,
wherein the substrate, the lower mirror structure, the interior light generating region, the upper mirror structure, and the spatial modulation region are all monolithically integrated,
wherein the lower mirror structure is closer to the substrate than the upper mirror structure, and the interior light generating region is located between the lower and upper mirror structures, and
wherein at least one of:
the VCSEL device is configured to emit light through the substrate;
the substrate is located between the interior light generating region and the exterior light emitting surface;
the spatial modulation region is located between the lower mirror structure and the exterior light emitting surface; and
the lower mirror structure, the interior light generating region, and the upper mirror structure are located to, at, or on, a first side of the substrate, and the spatial modulation region is located to, at, or on, a second side of the substrate opposite to the first side of the substrate.

15. A VCSEL device as claimed in claim 14, wherein the spatial modulation region is defined by the substrate at the second side of the substrate.

16. A VCSEL device as claimed in claim 14, wherein at least one of:
the spatial modulation region comprises, or is formed from, material grown epitaxially, or deposited on, the second side of the substrate;
the spatial modulation region comprises the same material of which the substrate comprises; and
the spatial modulation region comprises a polymer material and/or a dielectric material.

17. A VCSEL device as claimed in claim 1, wherein the interior light generating region, the spatial modulation region, and the exterior light emitting surface are arranged along a VCSEL axis, and wherein at least one of:
the spatial modulation region is configured so that the VCSEL device emits a beam of light along a predetermined direction or light emitting axis, wherein the predetermined direction or light emitting axis defines a non-zero angle relative to the VCSEL axis;
the spatial modulation region is configured so that the VCSEL device emits a beam of light having a predetermined beam divergence; and
the spatial modulation region is configured so that the VCSEL device emits a beam of light having a predetermined shape or structure transverse to a direction of propagation so that the beam of light forms a predetermined spot or pattern of light when projected onto a surface.

18. A plurality of VCSEL devices, each VCSEL device comprising a VCSEL device as claimed in claim 1, wherein the plurality of VCSEL devices are formed or monolithically integrated on a common substrate, wherein the spatial modulation region of each VCSEL device defines a corresponding outer surface which is directed away from the corresponding interior light generating region, wherein the corresponding outer surface of the spatial modulation region of each VCSEL device has a corresponding uneven profile, and wherein the profiles of the outer surfaces of the spatial modulation regions of at least two of the VCSEL devices are the same or different or the profile of the outer surface of the spatial modulation region of each VCSEL device is configured so as to emit a corresponding shaped beam so that the plurality of VCSEL devices emit a plurality of shaped beams which combine, or which are superimposed, to provide a desired or predetermined beam pattern or light intensity distribution in the far field.

19. A method for use in manufacturing a vertical cavity surface emitting laser (VCSEL) device, the VCSEL device comprising an exterior light emitting surface, and the method comprising:
monolithically integrating a spatial modulation region of the VCSEL device with an interior light generating region of the VCSEL device so that the spatial modulation region is located between the interior light generating region and the exterior light emitting surface,
wherein the spatial modulation region is configured to shape the light generated by the interior light generating region before the generated light is emitted from the exterior light emitting surface.

20. A method as claimed in claim 19, comprising:
monolithically integrating the interior light generating region and the spatial modulation region with a substrate so that the substrate is located between the interior light generating region and the exterior light emitting surface; and
selecting a thickness of the substrate so that the VCSEL device emits a light beam of a predetermined size at the light emitting surface.

21.-22. (canceled)
